(19) United States
(12) Patent Application Publication
(10) Pub. No.: US 2018/0210305 A1
(43) Pub. Date: Jul. 26, 2018

(54) ARRAY SUBSTRATE, DISPLAY PANEL AND DISPLAY APPARATUS HAVING THE SAME, AND FABRICATING METHOD THEREOF

(71) Applicants: BOE TECHNOLOGY GROUP CO., LTD., Beijing (CN); HEFEI XINSHENG OPTOELECTRONICS TECHNOLOGY CO., LTD., Hefei (CN)

(72) Inventors: Jilei Gao, Beijing (CN); Jinliang Liu, Beijing (CN); Mo Chen, Beijing (CN); Hongjiang Luo, Beijing (CN); Zuwen Liu, Beijing (CN)

(73) Assignees: BOE TECHNOLOGY GROUP CO., LTD., Beijing (CN); HEFEI XINSHENG OPTOELECTRONICS TECHNOLOGY CO., LTD., Hefei (CN)

(21) Appl. No.: 15/529,885

(22) PCT Filed: Oct. 21, 2016
(86) PCT No.: PCT/CN2016/102840

§ 371 Date: May 25, 2017

(30) Foreign Application Priority Data
Apr. 14, 2016 (CN) 201610232470.X

(51) Int. Cl. G02F 1/1362; G02F 1/1333; G09G 3/00; H01L 27/12; G02F 1/13

(52) U.S. Cl. CPC G02F 1/136286; G02F 1/1333; G02F 2001/13629; H01L 27/124; G02F 1/1309; G09G 3/006

(57) ABSTRACT

The present application discloses an array substrate including a base substrate, a first signal line layer on the base substrate having a plurality of first signal lines, an insulating layer on a side of the first signal line layer distal to the base substrate, a second signal line layer having a plurality of second signal lines on a side of the insulating layer distal to the first signal line layer; the plurality of second signal lines crossing over the plurality of first signal lines defining a plurality of subpixels, a passivation layer on a side of the second signal line layer distal to the insulating layer, and a test electrode layer having a plurality of test electrodes on a side of the passivation layer distal to the second signal line layer; each of the test electrode electrically connected to one of a first signal line and a second signal line.

### CROSS-REFERENCE TO RELATED APPLICATION

This application claims priority to Chinese Patent Application No. 201610232470.X, filed on Apr. 14, 2016, the contents of which are incorporated by reference in the entirety.

### TECHNICAL FIELD

The present invention relates to an array substrate, a display panel and display apparatus having the same, and a fabricating method thereof.

### BACKGROUND

Liquid crystal display panels have found a wide variety of applications. Typically, a liquid crystal display panel includes a color filter substrate and an array substrate facing each other. Thin film transistors, gate lines, data lines, pixel electrodes, common electrodes, and common electrode lines are disposed on the array substrate or the color filter substrate. Between the array substrate and the color filter substrate, a liquid crystal material is injected to form a liquid crystal layer. A passivation layer is deposited on the thin film transistor. A pixel electrode layer is disposed on the passivation layer.

### SUMMARY

In one aspect, the present disclosure provides an array substrate comprising a base substrate; a first signal line layer on the base substrate comprising a plurality of first signal lines; an insulating layer on a side of the first signal line layer distal to the base substrate; a second signal line layer comprising a plurality of second signal lines on a side of the insulating layer distal to the first signal line layer; the plurality of second signal lines crossing over the plurality of first signal lines defining a plurality of subpixels; a passivation layer on a side of the second signal line layer distal to the insulating layer; and a test electrode layer comprising a plurality of test electrodes on a side of the passivation layer distal to the second signal line layer; each of the test electrode electrically connected to one of a first signal line and a second signal line.

Optionally, the array substrate further comprises a plurality of vias extending through the passivation layer and insulating layer; wherein one of the plurality of test electrodes is electrically connected to the first signal line through one of the plurality of vias.

Optionally, the array substrate further comprises a plurality of vias extending through the passivation layer; wherein one of the plurality of test electrodes is electrically connected to the second signal line through one of the plurality of vias.

Optionally, the plurality of test electrodes comprise a plurality of first test electrodes and a plurality of second test electrodes; each of the plurality of first test electrodes electrically connected to a first signal line; and each of the plurality of second test electrodes electrically connected to a second signal line.

Optionally, the array substrate further comprises a plurality of first vias extending through the passivation layer and insulating layer; each of the plurality of first test electrodes electrically connected to the first signal line through a first via; and a plurality of second vias extending through the passivation layer; each of the plurality of second test electrodes electrically connected to the second signal line through a second via.

Optionally, the array substrate further comprises a pixel electrode layer comprising a plurality of pixel electrodes, each of which electrically connected to a drain electrode in a subpixel; wherein the pixel electrode layer and the test electrode layer are in a same layer.

Optionally, the plurality of test electrodes protrude out of an external surface of the passivation layer.

Optionally, the first signal line is a gate line, the second signal line is a data line.

Optionally, the array substrate further comprises a gate electrode layer comprising a plurality of gate electrodes in a plurality of subpixels; the gate electrode layer and the first signal line layer are in a same layer; and a source electrode and drain electrode layer comprising a plurality of source electrodes and drain electrodes in the plurality of subpixels; the source electrode and drain electrode layer and the second signal line layer are in a same layer.

Optionally, the first signal line and the second signal line are different signal lines selected from a gate line and a data line.

Optionally, the first signal line is a data line, the second signal line is a gate line.

Optionally, the array substrate further comprises a source electrode and drain electrode layer comprising a plurality of source electrodes and drain electrodes in a plurality of subpixels; the source electrode and drain electrode layer and the first signal line layer are in a same layer; and a gate electrode layer comprising a plurality of gate electrodes in the plurality of subpixels; the gate electrode layer and the second signal line layer are in a same layer.

In another aspect, the present disclosure provides a method of fabricating an array substrate, comprising forming a first signal line layer comprising a plurality of first signal lines on a base substrate; forming an insulating layer on a side of the first signal line layer distal to the base substrate; forming a second signal line layer comprising a plurality of second signal lines on a side of the insulating layer distal to the first signal line layer; the plurality of second signal lines crossing over the plurality of first signal lines defining a plurality of subpixels; forming a passivation layer on a side of the second signal line layer distal to the insulating layer; and forming a test electrode layer comprising a plurality of test electrodes on a side of the passivation layer distal to the second signal line layer; each of the test electrode electrically connected to one of a first signal line and a second signal line.

Optionally, the method further comprises forming a plurality of vias extending through the passivation layer and insulating layer, wherein one of the plurality of test electrodes is electrically connected to the first signal line through one of the plurality of vias.

Optionally, the method further comprises forming a plurality of vias extending through the passivation layer; wherein one of the plurality of test electrodes is electrically connected to the second signal line through one of the plurality of vias.

Optionally, the step of forming the test electrode layer comprises forming a plurality of first test electrodes; and forming a plurality of second test electrodes; wherein each of the plurality of first test electrodes electrically connected to a first signal line; and each of the plurality of second test electrodes electrically connected to a second signal line.

Optionally, the method further comprises forming a plurality of first vias extending through the passivation layer and insulating layer; each of the plurality of first test electrodes electrically connected to the first signal line through a first via; and forming a plurality of second vias extending through the passivation layer; each of the plurality of second test electrodes electrically connected to the second signal line through a second via.

Optionally, the step of forming the plurality of first vias comprises forming a plurality of first sub-vias subsequent to the step of forming the insulating layer and prior to the step of forming the passivation layer, the plurality of first sub-vias extending through the insulating layer, each of the plurality of first sub-vias exposing a portion of the first signal line; and forming a plurality of second sub-vias subsequent to the step of forming the passivation layer; the plurality of second sub-vias extending through the passivation layer, each of the plurality of second sub-vias connected to a first sub-via, thereby forming the plurality of first vias extending through the passivation layer and the insulating layer.

Optionally, the step of forming the plurality of first vias and the step of forming the plurality of second vias are performed in a single process subsequent to the step of forming the passivation layer.

In another aspect, the present disclosure provides a display panel comprising an array substrate described herein or fabricated by a method described herein.

In another aspect, the present disclosure provides a display apparatus comprising a display panel described herein.

### BRIEF DESCRIPTION OF THE FIGURES

The following drawings are merely examples for illustrative purposes according to various disclosed embodiments and are not intended to limit the scope of the present invention.

FIG. 1A is a diagram illustrating the structure of an array substrate in some embodiments.

FIG. 1B shows a cross-sectional view along the A-A′ direction of the array substrate in FIG. 1A.

FIG. 2 is a diagram illustrating the structure of an array substrate having a first signal line layer in some embodiments.

FIG. 3 is a diagram illustrating the structure of an array substrate having a second signal line layer in some embodiments.

FIG. 4 is a flow chart illustrating a method of fabricating an array substrate in some embodiments.

FIG. 5 is a flow chart illustrating a method of fabricating an array substrate in some embodiments.

FIG. 6 is a diagram illustrating a process of forming a first signal line layer on a base substrate.

FIG. 7 is a diagram illustrating a process of forming a second signal line layer on a gate insulating layer.

### DETAILED DESCRIPTION

The disclosure will now describe more specifically with reference to the following embodiments. It is to be noted that the following descriptions of some embodiments are presented herein for purpose of illustration and description only. It is not intended to be exhaustive or to be limited to the precise form disclosed.

Conventional array substrates typically include a base substrate; a first signal line layer on the base substrate having a plurality of rows of first signal lines; a gate insulating layer on a side of the first signal line layer distal to the base substrate; a second signal line layer having a plurality of columns of second signal lines on a side of the gate insulating layer distal to the first signal line layer; a passivation layer on a side of the second signal line layer distal to the gate insulating layer, and a pixel electrode layer on a side of the passivation layer distal to the second signal line layer. The first signal line and the second signal line are different signal lines selected from a gate line and a data line.

In conventional array substrates, the signal lines such as gate lines and data lines are packaged in the array substrate and are not accessible externally. In the manufacturing process of an array substrate, often it is needed to test electrical characteristics of a thin film transistor in the array substrate after the array substrate is assembled in a production line, to ensure that the array substrate meets the manufacturing standards. Similarly, examination of an array substrate having a defect often involves electrical characteristics measurement of the thin film transistor in the array substrate, e.g., measurement of resistance and capacitance. To measure electrical characteristics of components in the conventional array substrates, it is required to dissemble at least of a portion of the array substrate, e.g., the base substrate, to make the signal lines accessible. During the dissembling process, the base substrate is prone to physical damage because the base substrate is typically made of thin glass. Similarly, repairing signal line open circuit is impossible in conventional array substrates without dissembling the array substrate. The production yield in conventional array substrates is adversely affected due to these disadvantages.

Accordingly, the present disclosure provides an array substrate, a display panel and display apparatus having the same, and a fabricating method thereof that substantially obviate one or more of the problems due to limitations and disadvantages of the related art. In one aspect, the present disclosure provides a novel array substrate. In some embodiments, the array substrate includes a base substrate; a first signal line layer on the base substrate having a plurality of first signal lines; an insulating layer on a side of the first signal line layer distal to the base substrate; a second signal line layer having a plurality of second signal lines on a side of the insulating layer distal to the first signal line layer; the plurality of second signal lines crossing over the plurality of first signal lines defining a plurality of subpixels; a passivation layer on a side of the second signal line layer distal to the insulating layer; and a test electrode layer having a plurality of test electrodes on a side of the passivation layer distal to the second signal line layer; each of the test electrode electrically connected to one of a first signal line and a second signal line. The first signal line and the second signal line are different signal lines. Optionally, the first signal line and the second signal line are different signal lines selected from a gate line and a data line. Optionally, the first signal line and the second signal line are different signal lines selected from a common electrode signal line and a data line. Optionally, the first signal line and the second signal line are different signal lines selected from a common electrode signal line and a gate line. Optionally, the insulating layer is a gate insulating layer.

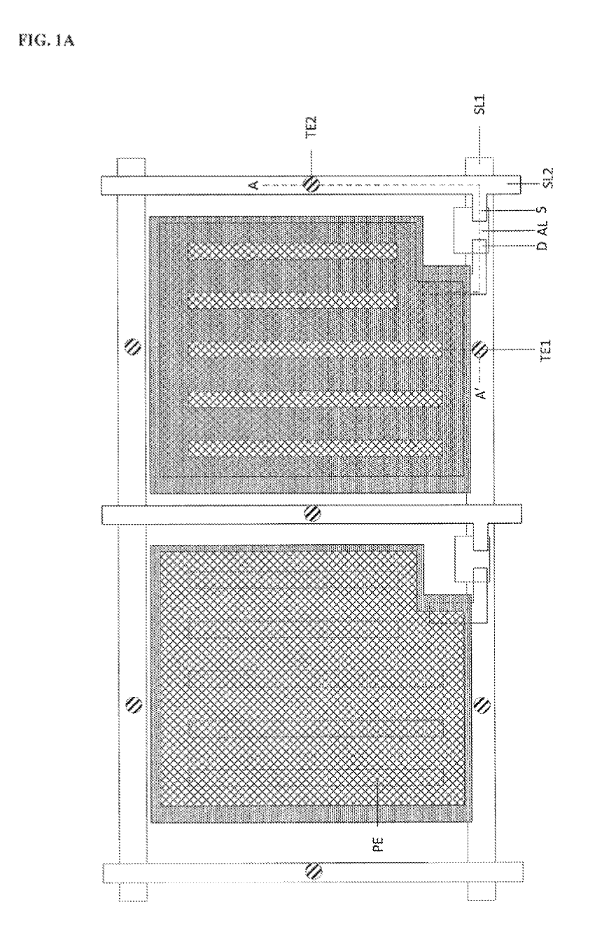

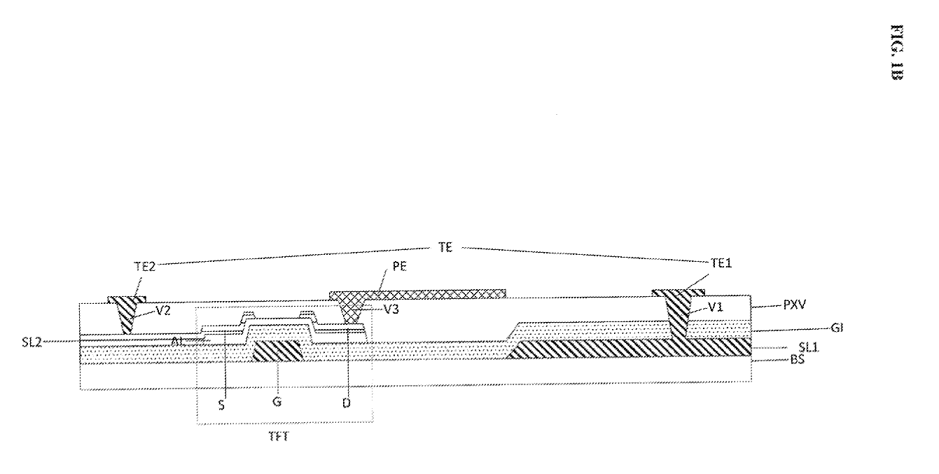

FIG. 1A is a diagram illustrating the structure of an array substrate in some embodiments. FIG. 1B shows a cross-sectional view along the A-A′ direction of the array substrate in FIG. 1A. Referring to FIGS. 1A and 1B, the array substrate in the embodiment includes a base substrate BS; a first signal line layer SL1 on the base substrate BS having a plurality of rows of first signal lines; a gate insulating layer GI on a side of the first signal line layer SL1 distal to the base substrate BS; a second signal line layer SL2 having a plurality of columns of second signal lines on a side of the gate insulating layer GI distal to the first signal line layer SL; a passivation layer PXV on a side of the second signal line layer SL2 distal to the gate insulating layer GI; and a test electrode layer TE having a plurality of test electrodes on a side of the passivation layer PXV distal to the second signal line layer SL2; each of the test electrode TE electrically connected to one of a first signal line SL1 and a second signal line SL2. The plurality of second signal lines SL2 cross over the plurality of first signal lines SL1 defining a plurality of subpixels. The first signal line and the second signal line are different signal lines selected from a gate line and a data line.

Referring to FIGS. 1A and 1B, the test electrode layer TE includes a plurality of first test electrodes TE1 and a plurality of second test electrodes TE2. Each of the plurality of first test electrodes TE1 is electrically connected to a first signal line SL1. Each of the plurality of second test electrodes TE2 is electrically connected to a second signal line SL2.

Referring to FIGS. 1A and 1B, the array substrate further includes a plurality of first vias V1 extending through the passivation layer PXV and gate insulating layer GI. Each of the plurality of first test electrodes TE1 is electrically connected to the first signal line SL1 through a first via V1. The array substrate further includes a plurality of second vias V2 extending through the passivation layer PXV; each of the plurality of second test electrodes TE2 is electrically connected to the second signal line SL2 through a second via V2.

Optionally, the array substrate includes only a plurality of first test electrodes but not a plurality of second test electrodes. Accordingly, the array substrate includes only a plurality of first vias but not a plurality of second vias. Optionally, the array substrate includes only a plurality of second test electrodes but not a plurality of first test electrodes. Accordingly, the array substrate includes only a plurality of second vias but not a plurality of first vias. Optionally, the array substrate includes both a plurality of first test electrodes and a plurality of second test electrodes. Accordingly, the array substrate includes both a plurality of first vias and a plurality of second vias.

In some embodiments, the plurality of rows of first signal lines and the plurality of columns of second signal lines cross over each other defining a plurality of subpixels. Each of the plurality of subpixels includes a driving thin film transistor having a gate electrode, a source electrode and a drain electrode.

As shown in FIGS. 1A and 1B, the array substrate further includes a pixel electrode layer PE having a plurality of pixel electrodes, each of which electrically connected to a drain electrode D in a subpixel. Optionally, the pixel electrode layer PE and the test electrode layer TE are in a same layer. The pixel electrode layer PE is electrically connected to a drain electrode D through a third via V3.

In some embodiments, each of the plurality of subpixels includes a thin film transistor for driving image display of the array substrate. Optionally, the thin film transistor is a bottom gate type thin film transistor (see, e.g., the TFT in FIG. 1B). In a bottom gate type thin film transistor, the array substrate includes a base substrate, a gate electrode layer on the base substrate, a gate insulating layer on a side of the gate electrode layer distal to the base substrate, a source electrode and drain electrode layer on a side of the gate insulating layer distal to the gate electrode layer, and a passivation layer on a side of the source electrode and drain electrode layer distal to the gate insulating layer. Optionally, the array substrate further includes an active layer on a side of the gate insulating layer distal to the gate electrode layer, the active layer having a channel region and a source electrode and drain electrode contact region. Optionally, the array substrate further includes a pixel electrode layer on a side of the passivation layer distal to the source electrode and drain electrode layer. Optionally, the array substrate further includes a gate line layer in a same layer as the gate electrode layer. Optionally, the array substrate further includes a data line layer in a same layer as the source electrode and drain electrode layer. The first signal line layer is the gate line layer and the second signal line layer is the data line layer.

Optionally, the thin film transistor is a top gate type thin film transistor. In a top gate type thin film transistor, the array substrate includes a base substrate, a source electrode and drain electrode layer on the base substrate, a gate insulating layer on a side of the source electrode and drain electrode layer distal to the base substrate, a gate electrode layer on a side of the gate insulating layer distal to the source electrode and drain electrode layer, and a passivation layer on a side of the gate electrode layer distal to the gate insulating layer. Optionally, the array substrate further includes an active layer on a side of the gate insulating layer distal to the gate electrode layer, the active layer having a channel region and a source electrode and drain electrode contact region. Optionally, the array substrate further includes a pixel electrode layer on a side of the passivation layer distal to the source electrode and drain electrode layer. Optionally, the array substrate further includes a gate line layer in a same layer as the gate electrode layer. Optionally, the array substrate further includes a data line layer in a same layer as the source electrode and drain electrode layer. The first signal line layer is the data line layer and the second signal line layer is the gate line layer.

Optionally, the test electrodes are evenly distributed in the array substrate. For example, each subpixel of the array substrate may correspond to one test electrode. Optionally, each subpixel of the array substrate may correspond to one first test electrode. Optionally, each subpixel of the array substrate may correspond to one second test electrode. Optionally, each subpixel of the array substrate may correspond to one first test electrode and one second test electrode. Optionally, each subpixel of the array substrate may correspond to a plurality of first test electrodes. Optionally, each subpixel of the array substrate may correspond to a plurality of second test electrodes. Optionally, each subpixel of the array substrate may correspond to a plurality of first test electrodes and a plurality of second test electrodes. Optionally, the test electrodes are distributed in the array substrate so that a plurality of subpixel correspond to one test electrode. Optionally, a plurality of subpixels correspond to one first test electrode. Optionally, a plurality of subpixels correspond to one second test electrode. Optionally, a plurality of subpixels correspond to one first test electrode and one second test electrode. Optionally, each pixel having one or more subpixel corresponds to one test electrode. Optionally, each pixel having one or more subpixel corresponds to one first test electrode. Optionally, each pixel having one or more subpixel corresponds to one second test electrode. Optionally, each pixel having one or more subpixel corresponds to one first test electrode and one second test electrode.

As compared to conventional array substrates, the present array substrate includes a test electrode layer that is accessible on an external surface of the passivation layer. For example, in some embodiments, the test electrode may protrude out of an external surface of the passivation layer. The test electrode layer is electrically connected to at least one of a first signal line and a second signal line (e.g., one or both of a gate line and a data line). By having the test electrode layer accessible at the external surface of the passivation layer, electrical characteristics of internal signal lines (e.g., the first signal lines and the second signal lines) may be conveniently measured while maintaining the array substrate intact, i.e., without dissembling the array substrate. In addition, signal line open circuit between two adjacent test electrodes may be repaired by electrically connecting two adjacent test electrodes on the passivation layer. Thus, significant product yield enhancement may be achieved by having the present array substrate.

Any appropriate conductive material may be used for making the test electrode layer. Optionally, the test electrode layer is made of a metal electrode material. Optionally, the test electrode layer is made of a transparent electrode material.

In some embodiments, the test electrode layer (including the first test electrode and the second test electrode) is made of a transparent electrode material. Examples of appropriate transparent electrode materials include, but are not limited to, indium tin oxide, indium zinc oxide, transparent metals (e.g., nano-silver), and a combination thereof. Optionally, the pixel electrode layer is made of a transparent electrode material. Optionally, the pixel electrode layer and the test electrode layer are made of a same transparent electrode material. Optionally, the pixel electrode layer and the test electrode layer are made in a same patterning process, e.g., using a same mask plate.

Depending on the manufacturing needs and other design reasons, the vias (including the first via, the second via, and the third via) may be made of any appropriate shape and size, regular or irregular. Examples of appropriate shapes include, but are not limited to, a circular shape, a triangular shape, a rectangular shape, a square shape, etc.

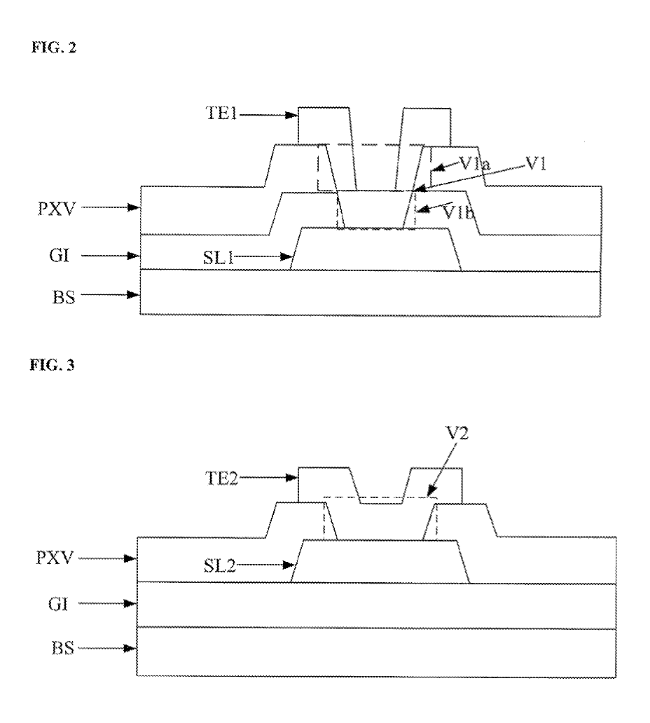

FIG. 2 is a diagram illustrating the structure of an array substrate having a first signal line layer in some embodiments. Referring to FIG. 2, the array substrate in the embodiment is a bottom gate type array substrate, i.e., the first signal line SL1 is a gate line. The array substrate includes a base substrate BS, a gate electrode (not shown in FIG. 2) and a gate line layer SL1, a gate insulating layer GI on a side of the SL1 distal to the base substrate BS, a passivation layer PXV on a side of the gate insulating layer GI distal to the gate line layer SL1, and a test electrode layer having a first test electrode TE1 on a side of the passivation layer PXV distal to the gate insulating layer GI. The array substrate further includes a first via V1 extending through the passivation layer PXV and the gate insulating layer GI, the first test electrode TE1 is electrically connected to the gate line layer SL through the first via V1. The first via V1 may be a via formed in a single etching step extending through the passivation layer PXV and the gate insulating layer GI. Optionally, the first via V1 may include two sub-vias V1a and V1b formed in two steps. The first sub-via V1a extends through the passivation layer PXV, and the second sub-via V1b extends through the gate insulating layer GI. The first sub-via V1a is connected to the second sub-via V1b, thereby forming a first via V1 extending through both the passivation layer PXV and the gate insulating layer GI. By having the first test electrode in the array substrate, the electrical characteristics of the gate lines may be conveniently measured while maintaining the array substrate intact, and gate line open circuit between two adjacent first test electrodes may be repaired by electrically connecting two adjacent first test electrodes on the passivation layer. In contrast, gate line electrical characteristics measurement or gate line open circuit repair requires dissembling the array substrate, a process proven to be complicated and often leading to array substrate damage.

FIG. 3 is a diagram illustrating the structure of an array substrate having a second signal line layer in some embodiments. Referring to FIG. 3, the array substrate in the embodiment is a bottom gate type array substrate, i.e., the second signal line SL2 is a data line. The array substrate includes a base substrate BS, a gate insulating layer GI on the base substrate BS, a data line layer SL2 on a side of the gate insulating layer GI distal to the base substrate BS, a passivation layer PXV on a side of the data line layer SL2 distal to the gate insulating layer GI, and a test electrode layer having a second test electrode TE2 on a side of the passivation layer PXV distal to the data line layer SL2. The array substrate further includes a second via V2 extending through the passivation layer PXV, the second test electrode TE2 is electrically connected to the data line layer SL2 through the second via V2. By having the second test electrode in the array substrate, the electrical characteristics of the data lines may be conveniently measured while maintaining the array substrate intact, and data line open circuit between two adjacent second test electrodes may be repaired by electrically connecting two adjacent second test electrodes on the passivation layer. In contrast, data line electrical characteristics measurement or data line open circuit repair requires dissembling the array substrate, a process proven to be complicated and often leading to array substrate damage.

The array substrate may be an array substrate of any appropriate mode. Examples of appropriate array substrates include, but are not limited to, a Twisted Nematic (TN) mode array substrate and an Advanced Super Dimension Switch (ADS) mode array substrate.

In the manufacturing process of an array substrate, often it is needed to test electrical characteristics of a thin film transistor in the array substrate after the array substrate is assembled in a production line, to ensure that the array substrate meets the manufacturing standards. Similarly, examination of an array substrate having a defect often involves electrical characteristics measurement of the thin film transistor in the array substrate, e.g., measurement of resistance and capacitance. In conventional array substrates, the signal lines such as gate lines and data lines are sealed in the array substrate and are not accessible externally. To measure electrical characteristics of components in the array substrate, it is required to dissemble the array substrate. During the dissembling process, the base substrate is prone to physical damage because the base substrate is typically made of thin glass. Similarly, repairing signal line open circuit is impossible in conventional array substrates without dissembling the array substrate. The production yield in conventional array substrates is affected due to these disadvantages.

By having a test electrode layer accessible on the external surface of the passivation layer, the electrical characteristics of the thin film transistor may be conveniently conducted without dissembling the array substrate first. For example, resistance of a signal line (e.g., a gate line or a data line) between any two test electrodes, and coupling capacitance between signal lines, may be conveniently measured using the test electrodes, e.g., by laser cutting technique. Moreover, signal line open circuit may be conveniently repaired by electrically connected two adjacent test electrodes. Optionally, the repairing process includes one or more of a laser cutting process, a laser chemical vapor deposition (Laser CVD) process, and a laser welding process. For example, the open portions of the signal lines may be electrically connected with tungsten powder.

In another aspect, the present disclosure provides a method of fabricating an array substrate. In some embodiments, the method includes forming a first signal line layer having a plurality of rows of first signal lines on a base substrate; forming a gate insulating layer on a side of the first signal line layer distal to the base substrate; forming a second signal line layer having a plurality of columns of second signal lines on a side of the gate insulating layer distal to the first signal line layer; forming a passivation layer on a side of the second signal line layer distal to the gate insulating layer; and forming a test electrode layer having a plurality of test electrodes on a side of the passivation layer distal to the second signal line layer, each of the test electrode electrically connected to one of a first signal line and a second signal line. The plurality of second signal lines cross over the plurality of first signal lines defining a plurality of subpixels. The first signal line and the second signal line are different signal lines selected from a gate line and a data line.

In some embodiments, the method further includes forming a plurality of vias extending through the passivation layer and gate insulating layer; each of the plurality of test electrodes electrically connected to the first signal line through one of the plurality of vias. In some embodiments, the method further includes forming a plurality of vias extending through the passivation layer, wherein each of the plurality of test electrodes electrically connected to the second signal line through one of the plurality of vias.

In some embodiments, the step of forming the test electrode layer includes forming a plurality of first test electrodes; and forming a plurality of second test electrodes. Each of the plurality of first test electrodes is electrically connected to a first signal line; and each of the plurality of second test electrodes is electrically connected to a second signal line. Accordingly, the method further includes forming a plurality of first vias extending through the passivation layer and gate insulating layer and forming a plurality of second vias extending through the passivation layer. Each of the plurality of first test electrodes is electrically connected to the first signal line through a first via, and each of the plurality of second test electrodes is electrically connected to the second signal line through a second via.

In some embodiments, the plurality of first vias may be formed in two steps. The first step is performed subsequent to the formation of the gate insulating layer and prior to the formation of the passivation layer. The second step is performed subsequent to the formation of the passivation layer. Optionally, the step of forming the plurality of first vias includes forming a plurality of first sub-vias subsequent to the step of forming the gate insulating layer and prior to the step of forming the passivation layer and forming a plurality of second sub-vias subsequent to the step of forming the passivation layer. The plurality of first sub-vias extend through the gate insulating layer, exposing a portion of the first signal line. The plurality of second sub-vias extend through the passivation layer. Each of the plurality of second sub-vias is connected to a first sub-via. The first sub-via and the second sub-via connected together to form a first via first vias extending through the passivation layer and the gate insulating layer.

In some embodiments, the first sub-vias and the second sub-vias may be formed in a single process, e.g., using a single mask, subsequent to the formation of the passivation layer. For example, using a mask plate having a pattern corresponding to the plurality of first vias, the array substrate may be etched to form the plurality of first vias extending through both the passivation layer and the gate insulating layer.

In some embodiments, the plurality of first vias and the plurality of second vias may be formed in a single process, e.g., using a single mask, subsequent to the formation of the passivation layer. For example, subsequent to the formation of the passivation layer, a half-tone mask or a gray-tone mask may be used to pattern the array substrate to form the plurality of first vias and the plurality of second vias.

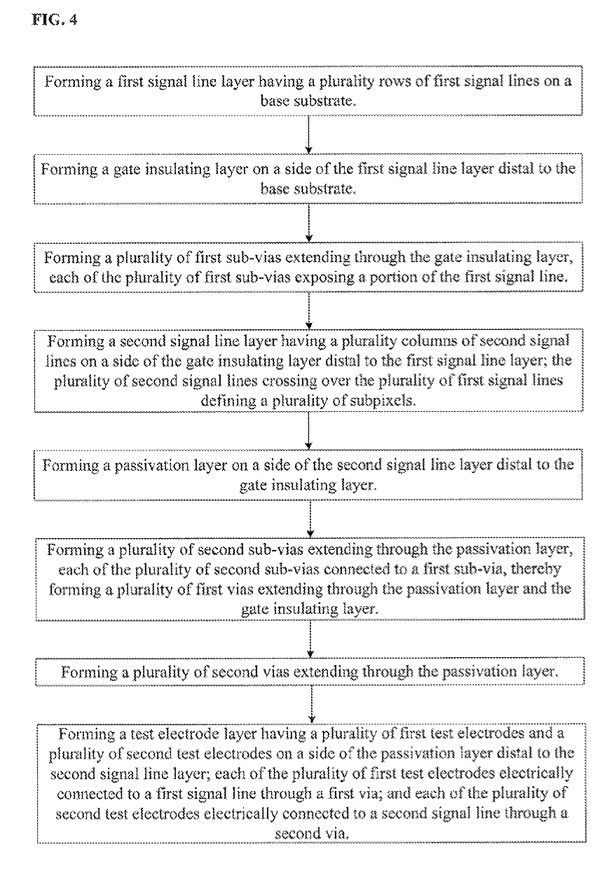

FIG. 4 is a flow chart illustrating a method of fabricating an array substrate in some embodiments. Referring to FIG. 4, the method in the embodiment includes forming a first signal line layer having a plurality of rows of first signal lines on a base substrate; forming a gate insulating layer on a side of the first signal line layer distal to the base substrate; forming a plurality of first sub-vias extending through the gate insulating layer, each of the plurality of first sub-vias exposing a portion of the first signal line; forming a second signal line layer having a plurality of columns of second signal lines on a side of the gate insulating layer distal to the first signal line layer; the plurality of second signal lines crossing over the plurality of first signal lines defining a plurality of subpixels; forming a passivation layer on a side of the second signal line layer distal to the gate insulating layer, forming a plurality of second sub-vias extending through the passivation layer, each of the plurality of second sub-vias connected to a first sub-via, thereby forming a plurality of first vias extending through the passivation layer and the gate insulating layer; forming a plurality of second vias extending through the passivation layer; and forming a test electrode layer having a plurality of first test electrodes and a plurality of second test electrodes on a side of the passivation layer distal to the second signal line layer; each of the plurality of first test electrodes electrically connected to a first signal line through a first via; and each of the plurality of second test electrodes electrically connected to a second signal line through a second via. The first signal line and the second signal line are different signal lines selected from a gate line and a data line.

In some embodiments, the first signal line is a gate line. Optionally, the method further includes forming a gate electrode layer in a same layer as the first signal line layer. In some embodiments, the second signal line is a data line. Optionally, the method further includes forming a source electrode and drain electrode layer in a same layer as the second signal line layer. In some embodiments, the method further includes forming a pixel electrode layer in a same layer as the test electrode layer. Optionally, the method further includes forming a plurality of third vias extending through the passivation layer, each of the plurality of pixel electrodes electrically connected to a drain electrode through a third via.

Optionally, the gate electrode layer and the first signal line layer (e.g., a gate line layer) are formed in a single patterning process. Optionally, the source electrode and drain electrode layer and the second signal line layer are formed in a single patterning process. Optionally, the pixel electrode layer and the test electrode layer are formed in a single patterning process.

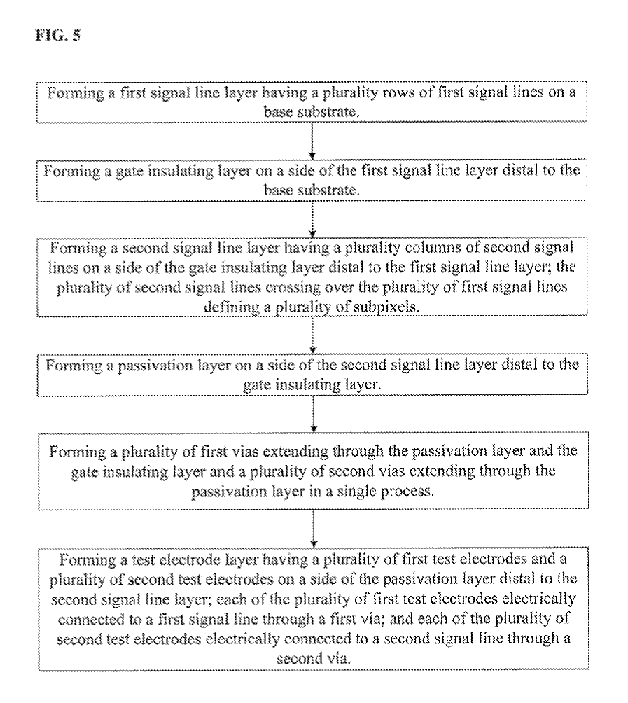

FIG. 5 is a flow chart illustrating a method of fabricating an array substrate in some embodiments. Referring to FIG. 5, the method in the embodiment includes forming a first signal line layer having a plurality of rows of first signal lines on a base substrate; forming a gate insulating layer on a side of the first signal line layer distal to the base substrate; forming a second signal line layer having a plurality of columns of second signal lines on a side of the gate insulating layer distal to the first signal line layer; the plurality of second signal lines crossing over the plurality of first signal lines defining a plurality of subpixels; forming a passivation layer on a side of the second signal line layer distal to the gate insulating layer; forming a plurality of first vias extending through the passivation layer and the gate insulating layer and a plurality of second vias extending through the passivation layer in a single process; and forming a test electrode layer having a plurality of first test electrodes and a plurality of second test electrodes on a side of the passivation layer distal to the second signal line layer, each of the plurality of first test electrodes electrically connected to a first signal line through a first via; and each of the plurality of second test electrodes electrically connected to a second signal line through a second via. The first signal line and the second signal line are different signal lines selected from a gate line and a data line.

In some embodiments, the first signal line is a gate line. Optionally, the method further includes forming a gate electrode layer in a same layer as the first signal line layer. In some embodiments, the second signal line is a data line. Optionally, the method further includes forming a source electrode and drain electrode layer in a same layer as the second signal line layer. In some embodiments, the method further includes forming a pixel electrode layer in a same layer as the test electrode layer. Optionally, the method further includes forming a plurality of third vias extending through the passivation layer, each of the plurality of pixel electrodes electrically connected to a drain electrode through a third via. Optionally, the step of forming the plurality of third vias and the step of forming the plurality of first vias and the plurality of second vias are performed in a single process.

Optionally, the gate electrode layer and the first signal line layer (e.g., a gate line layer) are formed in a single patterning process. Optionally, the source electrode and drain electrode layer and the second signal line layer are formed in a single patterning process. Optionally, the pixel electrode layer and the test electrode layer are formed in a single patterning process.

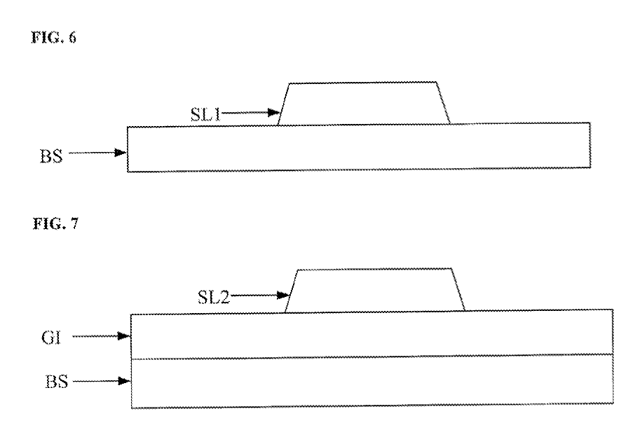

FIG. 6 is a diagram illustrating a process of forming a first signal line layer on a base substrate. In some embodiments, the process includes forming a conductive material layer (e.g., a metal layer) on the base substrate BS. Optionally, the process includes patterning the conductive material layer to form a first signal line layer SL1. When the first signal line is a gate line, the process includes patterning the conductive material layer to form a gate line layer. Optionally, the gate electrode and the gate line layer are formed in a single patterning process by patterning the conductive material layer on the base substrate BS. The patterning process may be performed by forming a photoresist layer on the base substrate, exposing and developing the photoresist layer using a mask plate having a pattern corresponding to the first signal line layer SL1 (and optionally the gate electrode layer), etching the conductive material layer thereby forming the first signal line layer SL1 (and optionally the gate electrode layer).

FIG. 7 is a diagram illustrating a process of forming a second signal line layer on a gate insulating layer. In some embodiments, the process includes forming a conductive material layer (e.g., a metal layer) on the gate insulating layer GI. Optionally, the process includes patterning the conductive material layer to form a second signal line layer SL2. When the second signal line is a data line, the process includes patterning the conductive material layer to form a data line layer. Optionally, the source electrode and drain electrode layer and the data line layer are formed in a single patterning process by patterning the conductive material layer on the gate insulating layer GI. Optionally, the process further includes forming an active layer (and channel region thereof) on the gate insulating layer GI. Optionally, the process includes forming a semiconductor material layer, a doped semiconductor material layer, and a conductive material layer on the gate insulating layer GI, followed by a single patterning process thereby forming an active layer, a data line layer, a source electrode and drain electrode layer, and a channel region on the active layer.

Any appropriate gate insulating materials and any appropriate fabricating methods may be used to make the gate insulating layer. For example, a gate insulating material may be deposited on the base substrate by a plasma-enhanced chemical vapor deposition (PECVD) process, a chemical vapor deposition (CVD), a sputtering process (e.g., magnetron sputtering), or a coating process. Examples of appropriate gate insulating materials include, but are not limited to, silicon oxide (SiO_{y}), silicon nitride (SiN_{y}, e.g., Si₃N₄), silicon oxynitride (SiOₓN_{y}). Optionally, the gate insulating layer GI may have a single-layer structure or a stacked-layer structure including two or more sub-layers (e.g., a stacked-layer structure including a silicon oxide sublayer and a silicon nitride sublayer). Optionally, the gate insulating layer has a thickness in the range of approximately 800 Å to approximately 6000 Å, e.g., approximately 3000 Å to approximately 5000 Å.

Any appropriate passivation layer materials and any appropriate fabricating methods may be used to make the passivation layer. For example, a passivation material may be deposited on the base substrate by a plasma-enhanced chemical vapor deposition (PECVD) process. Examples of appropriate passivation layer materials include, but are not limited to, an organic material such as a resin, and an inorganic material such as silicon oxide (SiO_{y}), silicon nitride (SiN_{y}, e.g., Si₃N₄), and silicon oxynitride (SiOₓN_{y}). Optionally, the passivation layer has a thickness in the range of approximately 1000 Å to approximately 6000 Å.

The array substrate fabricated by the present method includes a test electrode layer that is accessible on an external surface of the passivation layer. For example, in some embodiments, the test electrode may protrude out of an external surface of the passivation layer. The test electrode layer is electrically connected to at least one of a first signal line and a second signal line (e.g., one or both of a gate line and a data line). By having the test electrode layer accessible at the external surface of the passivation layer, electrical characteristics of internal signal lines (e.g., the first signal lines and the second signal lines) may be conveniently measured while maintaining the array substrate intact, i.e., without dissembling the array substrate. For example, resistance of a signal line (e.g., a gate line or a data line) between any two test electrodes, and coupling capacitance between signal lines, may be conveniently measured using the test electrodes, e.g., by laser cutting technique. In addition, signal line open circuit between two adjacent test electrodes may be repaired by electrically connecting two adjacent test electrodes on the passivation layer. Thus, significant product yield enhancement may be achieved by having the present array substrate.

In another aspect, the present disclosure provides a display panel having an array substrate described herein or fabricated by a method described herein. The present display panel includes an array substrate having a test electrode layer that is accessible on an external surface of the passivation layer. For example, in some embodiments, the test electrode may protrude out of an external surface of the passivation layer. The test electrode layer is electrically connected to at least one of a first signal line and a second signal line (e.g., one or both of a gate line and a data line). By having the test electrode layer accessible at the external surface of the passivation layer, electrical characteristics of internal signal lines (e.g., the first signal lines and the second signal lines) may be conveniently measured while maintaining the array substrate intact, i.e., without dissembling the array substrate. For example, resistance of a signal line (e.g., a gate line or a data line) between any two test electrodes, and coupling capacitance between signal lines, may be conveniently measured using the test electrodes, e.g., by laser cutting technique. In addition, signal line open circuit between two adjacent test electrodes may be repaired by electrically connecting two adjacent test electrodes on the passivation layer. Thus, significant product yield enhancement may be achieved by having the present array substrate.

In another aspect, the present disclosure provides a display apparatus having a display panel described herein. Examples of appropriate display apparatuses include, but are not limited to, an electronic paper, a mobile phone, a tablet computer, a television, a monitor, a notebook computer, a digital album, a GPS, etc.

The present display apparatus includes an array substrate having a test electrode layer that is accessible on an external surface of the passivation layer. For example, in some embodiments, the test electrode may protrude out of an external surface of the passivation layer. The test electrode layer is electrically connected to at least one of a first signal line and a second signal line (e.g., one or both of a gate line and a data line). By having the test electrode layer accessible at the external surface of the passivation layer, electrical characteristics of internal signal lines (e.g., the first signal lines and the second signal lines) may be conveniently measured while maintaining the array substrate intact, i.e., without dissembling the array substrate. For example, resistance of a signal line (e.g., a gate line or a data line) between any two test electrodes, and coupling capacitance between signal lines, may be conveniently measured using the test electrodes, e.g., by laser cutting technique. In addition, signal line open circuit between two adjacent test electrodes may be repaired by electrically connecting two adjacent test electrodes on the passivation layer. Thus, significant product yield enhancement may be achieved by having the present array substrate.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An array substrate, comprising:
a base substrate;
a first signal line layer on the base substrate comprising a plurality of first signal lines;
an insulating layer on a side of the first signal line layer distal to the base substrate;
a second signal line layer comprising a plurality of second signal lines on a side of the insulating layer distal to the first signal line layer; the plurality of second signal lines crossing over the plurality of first signal lines defining a plurality of subpixels;
a passivation layer on a side of the second signal line layer distal to the insulating layer; and
a test electrode layer comprising a plurality of test electrodes on a side of the passivation layer distal to the second signal line layer; each of the test electrode electrically connected to one of a first signal line and a second signal line.

2. The array substrate of claim 1, further comprising:
a plurality of vias extending through the passivation layer and insulating layer,
wherein one of the plurality of test electrodes is electrically connected to the first signal line through one of the plurality of vias.

3. The array substrate of claim 1, further comprising:
a plurality of vias extending through the passivation layer;
wherein one of the plurality of test electrodes is electrically connected to the second signal line through one of the plurality of vias.

4. The array substrate of claim 1, wherein
the plurality of test electrodes comprises a plurality of first test electrodes and a plurality of second test electrodes;
each of the plurality of first test electrodes electrically connected to a first signal line; and
each of the plurality of second test electrodes electrically connected to a second signal line.

5. The array substrate of claim 4, further comprising:
a plurality of first vias extending through the passivation layer and insulating layer, each of the plurality of first test electrodes electrically connected to the first signal line through a first via; and
a plurality of second vias extending through the passivation layer; each of the plurality of second test electrodes electrically connected to the second signal line through a second via.

6. The array substrate of claim 1, further comprising a pixel electrode layer comprising a plurality of pixel electrodes, each of which electrically connected to a drain electrode in a subpixel;
wherein the pixel electrode layer and the test electrode layer are in a same layer.

7. The array substrate of claim 1, wherein the plurality of test electrodes protrude out of an external surface of the passivation layer.

8. The array substrate of claim 1, wherein the first signal line is a gate line, the second signal line is a data line.

9. The array substrate of claim 8, further comprising:
a gate electrode layer comprising a plurality of gate electrodes in a plurality of subpixels; the gate electrode layer and the first signal line layer are in a same layer; and
a source electrode and drain electrode layer comprising a plurality of source electrodes and drain electrodes in the plurality of subpixels; the source electrode and drain electrode layer and the second signal line layer are in a same layer.

10. The array substrate of claim 1, wherein the first signal line and the second signal line are different signal lines selected from a gate line and a data line.

11. (canceled)

12. The array substrate of claim 11, further comprising:
a source electrode and drain electrode layer comprising a plurality of source electrodes and drain electrodes in a plurality of subpixels; the source electrode and drain electrode layer and the first signal line layer are in a same layer; and
a gate electrode layer comprising a plurality of gate electrodes in the plurality of subpixels; the gate electrode layer and the second signal line layer are in a same layer.

13. A display panel, comprising an array substrate of claim 1.

14. A display apparatus, comprising a display panel of claim 13.

15. A method of fabricating an array substrate, comprising:
forming a first signal line layer comprising a plurality of first signal lines on a base substrate;
forming an insulating layer on a side of the first signal line layer distal to the base substrate;
forming a second signal line layer comprising a plurality of second signal lines on a side of the insulating layer distal to the first signal line layer; the plurality of second signal lines crossing over the plurality of first signal lines defining a plurality of subpixels;
forming a passivation layer on a side of the second signal line layer distal to the insulating layer; and
forming a test electrode layer comprising a plurality of test electrodes on a side of the passivation layer distal to the second signal line layer; each of the test electrode electrically connected to one of a first signal line and a second signal line.

16. The method of claim 15, further comprising forming a plurality of vias extending through the passivation layer and insulating layer; wherein one of the plurality of test electrodes is electrically connected to the first signal line through one of the plurality of vias.

17. The method of claim 15, further comprising forming a plurality of vias extending through the passivation layer; wherein one of the plurality of test electrodes is electrically connected to the second signal line through one of the plurality of vias.

18. The method of claim 15, wherein the step of forming the test electrode layer comprises:
forming a plurality of first test electrodes; and
forming a plurality of second test electrodes;
wherein each of the plurality of first test electrodes electrically connected to a first signal line; and each of the plurality of second test electrodes electrically connected to a second signal line.

19. The method of claim 18, further comprising:
forming a plurality of first vias extending through the passivation layer and insulating layer; each of the plurality of first test electrodes electrically connected to the first signal line through a first via; and
forming a plurality of second vias extending through the passivation layer, each of the plurality of second test electrodes electrically connected to the second signal line through a second via.

20. The method of claim 19, wherein the step of forming the plurality of first vias comprises:
forming a plurality of first sub-vias subsequent to the step of forming the insulating layer and prior to the step of forming the passivation layer, the plurality of first sub-vias extending through the insulating layer, each of the plurality of first sub-vias exposing a portion of the first signal line; and
forming a plurality of second sub-vias subsequent to the step of forming the passivation layer; the plurality of second sub-vias extending through the passivation layer, each of the plurality of second sub-vias connected to a first sub-via, thereby forming the plurality of first vias extending through the passivation layer and the insulating layer.

21. The method of claim 19; wherein the step of forming the plurality of first vias and the step of forming the plurality of second vias are performed in a single process subsequent to the step of forming the passivation layer.
